(19) United States
(12) Patent Application Publication
(10) Pub. No.: US 2024/0213418 A1
(43) Pub. Date: Jun. 27, 2024

(54) Detection Film and Manufacturing Method Therefor, Detection Method and Device for Chip Bonding, and Classification Method

(71) Applicant: CHONGQING KONKA PHOTOELECTRIC TECHNOLLOGY RESEARCH INSTITUTE CO., LTD., Chongqing (CN)

(72) Inventor: Feng ZHAI, Chongqing (CN)

(21) Appl. No.: 17/910,345

(22) PCT Filed: Jul. 1, 2021
(86) PCT No.: PCT/CN2021/104112

§ 371 Date: Sep. 8, 2022

(51) Int. Cl. H01L 33/54; H01L 21/66; H01L 25/075; H01L 33/48

(52) U.S. Cl. CPC H01L 33/54; H01L 22/30; H01L 25/0753; H01L 33/486; H01L 2933/005

(57) ABSTRACT

The disclosure relates to a detection film and a manufacturing method therefor, a detection method and device for chip bonding, and a classification method. A detection film (2) covers a chip bonded to a circuit board (11), the detection film (2) is internally provided with colloidal crystal microspheres (22) arranged in order, and based on a Bragg reflection effect of the colloidal crystal microspheres, whether each chip is tilted is determined according to light reflected by the colloidal crystal microspheres (22) on the chip.

### CROSS REFERENCE

This application is a National Stage Filing of the PCT International Application No. PCT/CN2021/104112 filed on Jul. 1, 2021, the entirety of which is herein incorporated by reference.

### TECHNICAL FIELD

The disclosure relates to the field of chip detection, and particularly relates to a detection film and a manufacturing method therefor, a detection method and device for chip bonding, and a classification method.

### BACKGROUND

Mini light-emitting diode (LED) display is based on a state-of-the-art display technology employing inorganic semiconductor LED chips with a space of 0.6 mm-1.2 mm. Mini LED can be applied to large-screen high-definition display in professional fields such as monitoring and commanding, high-definition broadcasts, high-end cinemas and medical inspection or commercial fields such as outdoor advertisement, conference and exhibition, and office display. Being made of an inorganic semiconductor material, mini LED is visible in full color in outdoor strong light, with the brightness up to 5000 nit, photoelectric response up to a nanosecond level, and service life longer than 10 years. Generally, a mini LED display screen uses a printed circuit board (PCB). A PCB pad on the PCB and an LED chip pad are welded with tin or solder paste. As for the LED display, printing solder paste is used as a welding flux in most cases, and then the LED chip is bonded to a PCB substrate through the surface mounted technology (SMT), which requires reflow soldering by a high-temperature reflow oven at the end.

In the process of a reflow soldering process in a thermal environment of about 200° C., re-melting the welding flux is likely to cause tilt of bonded mini LED chips as well as a final difference of light-emitting angles of the mini LED chips, which will affect a display effect. At present, there is no effective detection means to detect whether the bonded mini LED chips are tilted.

Therefore, how to detect whether a bonded mini LED chip is tilted is an urgent problem to be solved.

### SUMMARY

In view of the defects in the realted art, an objective of the disclosure is to provide a detection film and a manufacturing method therefor, a detection method and device for chip bonding, and a classification method, so as to solve the problem of how to detect whether a mini light-emitting diode (LED) chip bonded to a circuit board is tilted in related technologies.

The disclosure provides a detection film. The detection film is configured to cover a chip bonded to a circuit board, and includes a film layer and colloidal crystal microspheres distributed in the film layer. The colloidal crystal microspheres are arranged in the film layer in order.

The detection film includes the colloidal crystal microspheres distributed in the film layer. The colloidal crystal microspheres are arranged in the film layer in order. During detection, the chip bonded to the circuit board may be covered with the detection film, and based on a Bragg reflection effect of the colloidal crystal microspheres, according to the characteristic that light reflected by colloidal crystal microspheres corresponding to chips having difference tilt angles after bonding varies, a tilt angle of each chip after bonding may be determined on the basis of light reflected by the colloidal crystal microspheres on the chip due to the Bragg reflection effect. In this way, whether the chip bonded to the circuit board is tilted is determined, that is, whether the chip (including, but not limited to, a mini LED chip) bonded to the circuit board is tilted is detected.

Based on the same inventive concept, the disclosure further provides a manufacturing method for a detection film. The detection film is configured to cover a chip bonded to a circuit board. The manufacturing method for a detection film includes:
Forming, on a bearing substrate, a colloidal crystal layer composed of colloidal crystal microspheres arranged in order; and
filling gaps at least between all the colloidal crystal microspheres with film materials, so as to form a film layer.

The detection film manufactured through the manufacturing method for a detection film is internally provided with the colloidal crystal microspheres arranged in order. Based on a Bragg reflection effect of the colloidal crystal microspheres, during detection, the chip bonded to the circuit board may be covered with the detection film, and a tilt angle of each chip after bonding may be determined on the basis of light reflected by the colloidal crystal microspheres on the chip due to the Bragg reflection effect. In this way, whether the chip bonded to the circuit board is tilted is determined, that is, whether the chip bonded to the circuit board is tilted is detected.

Based on the same inventive concept, the disclosure further provides a detection method for chip bonding. The detection method includes:
placing a chip bonded to a circuit board in a preset light environment, where the chip faces a light incident direction;
covering the chip with the detection film mentioned above; and
detecting light reflected by colloidal crystal microspheres on the chip, and determining, according to a detection result, a tilt angle of the chip after bonding.

According to the detection method for chip bonding, the chip bonded to the circuit board is placed in the preset light environment, and the chip is covered with the detection film mentioned above. The detection film is internally provided with the colloidal crystal microspheres arranged in order. Based on a Bragg reflection effect of the colloidal crystal microspheres, the tilt angle of each chip after bonding may be determined on the basis of the light reflected by the colloidal crystal microspheres on the chip due to the Bragg reflection effect. In this way, whether the chip bonded to the circuit board is tilted is determined, that is, whether the chip bonded to the circuit board is tilted is detected.

Based on the same inventive concept, the disclosure further provides a detection device for chip bonding. The detection device includes:
a light detection apparatus configured to, in a case where the chip bonded to a circuit board is placed in a preset light environment, the chip faces a light incident direction and the detection film mentioned above covers the chip, detect light reflected by colloidal crystal microspheres on the chip, and determine, according to a detection result, a tilt angle of the chip after bonding.

The light detection apparatus may determine a tilt angle of each chip after bonding on the basis of light reflected by the colloidal crystal microspheres on the chip due to a Bragg reflection effect. In this way, whether the chip bonded to the circuit board is tilted is determined, that is, whether the chip bonded to the circuit board is tilted is detected.

Based on the same inventive concept, the disclosure further provides a classification method for display panels. Each of the display panel includes a display back panel and one or more luminous chips bonded to the display back panel. The classification method includes:
Detecting, through the detection method for chip bonding mentioned above, tilt angles of the one or more luminous chips on each of the display panels after bonding; and
classifying each of the display panels according to the tilt angles.

According to the classification method for a display panel, the tilt angles of the luminous chips on the display panels after bonding may be detected through the detection method for chip bonding, and the display panels may be classified in a targeted manner according to the detected tilt angles, thereby being more conducive to later targeted and rational application and/or maintenance of the display panel.

Based on the same inventive concept, the disclosure further provides a manufacturing method for a display screen. The manufacturing method includes:
selecting at least two display panels from set display panels in various display panels classified through the classification method for a display panel mentioned above; and
splicing at least two selected display panels.

According to the manufacturing method for a display screen, a more rational display panel may be selected for splicing according to classes, thereby facilitating solving a problem of squint spots in a large line display screen, so as to improve overall quality of the display screen.

### BRIEF DESCRIPTION OF THE DRAWINGS

FIG. 1 is schematic diagram of a process of bonding a mini light-emitting diode (LED) chip to a circuit board in related technologies;

FIG. 2 is a structural schematic diagram of a detection film provided in an embodiment of the disclosure;

FIG. 3 is a schematic diagram of colloidal crystal microspheres arranged in order provided in an embodiment of the disclosure;

FIG. 4 is a schematic diagram of a flow of a manufacturing method for a detection film provided in another optional embodiment of the disclosure;

FIG. 5 is a schematic diagram of a process of forming a colloidal crystal layer provided in another optional embodiment of the disclosure;

FIG. 6 is a schematic diagram of a process of forming a film layer provided in another optional embodiment of the disclosure;

FIG. 7 is a schematic diagram of a process of forming a detection film provided in another optional embodiment of the disclosure;

FIG. 8 is a schematic diagram of a flow of a detection method for chip bonding provided in yet another optional embodiment of the disclosure;

FIG. 9 is a first schematic diagram showing a luminous chip covered with a detection film provided in yet another optional embodiment of the disclosure;

FIG. 10 is a second schematic diagram showing a luminous chip covered with a detection film provided in yet another optional embodiment of the disclosure;

FIG. 11 is a third schematic diagram showing a luminous chip covered with a detection film provided in yet another optional embodiment of the disclosure;

FIG. 12 is a fourth schematic diagram showing a luminous chip covered with a detection film provided in yet another optional embodiment of the disclosure;

FIG. 13 is a structural schematic diagram of a light detection apparatus provided in yet another optional embodiment of the disclosure;

FIG. 14 is a schematic diagram of a flow of a classification method for a display panel provided in another optional embodiment of the disclosure; and

FIG. 15 is a schematic diagram of a flow of a manufacturing method for a display screen provided in another optional embodiment of the disclosure.

### DESCRIPTION OF REFERENCE NUMERALS

11—circuit board, 12—circuit board pad, 13—mini LED chip, 2—detection film, 21—film layer, 22—colloidal crystal microsphere, 31—bearing substrate, 32—microsphere mixed solution layer, 33—film material solution layer, 41—display back panel, 42—luminous chip, and 43—packaging layer.

### DETAILED DESCRIPTION OF THE EMBODIMENTS

To facilitate understanding of the disclosure, the following will describe the disclosure more comprehensively with reference to relevant accompanying drawings. A preferred implementation of the disclosure is given in the accompanying drawings. However, the disclosure may be implemented in many different forms and is not limited to the implementations described herein. On the contrary, the implementations are provided for making contents disclosed to be understood more thoroughly and comprehensively.

Unless otherwise defined, all technical and scientific terms used herein have the same meanings as those commonly understood by those skilled in the technical field of the disclosure. The terms used in the description of the disclosure are merely for the purpose of describing particular implementations, and are not intended to limit the disclosure.

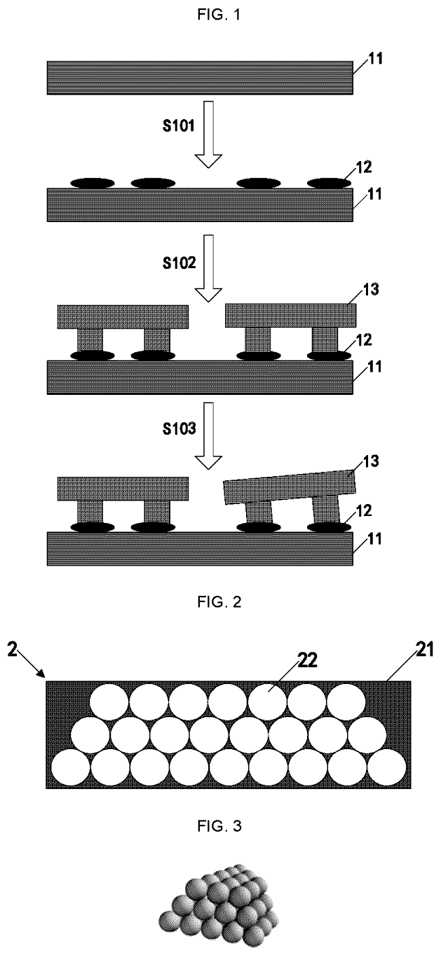

In related technologies, a mini light-emitting diode (LED) display screen uses a printed circuit board (PCB). A PCB pad on the PCB and an LED chip pad are welded by tin or solder paste. The LED display usually uses printing solder paste as a welding flux, and then bonds the LED chip to a PCB substrate through a surface mounted technology (SMT). Finally, it is often necessary to conduct reflow soldering by a high-temperature reflow oven. A manufacturing process is as shown in FIG. 1 and includes:
S101: a circuit board pad 12 is arranged in a bonding area of each chip on a circuit board 11.
S102: a mini LED chip 13 is transferred to the bonding area of each chip, so as to be properly connected to the corresponding circuit board pad 12.
S103: reflow soldering is conducted by a high-temperature reflow oven, so as to bond the mini LED chip 13 to the circuit board 11. In the process, a reflow soldering process is conducted in a thermal environment of about 200° ° C. In the process, re-melting of the circuit board pad 12 easily leads to tilting of a mini LED chip bonded to the circuit board, such as the mini LED chip 13 that is tilted as shown in FIG. 1, and finally to a difference of luminous angles of mini LED chips, which may affect a display effect. At present, there is no effective detection means to detect whether the mini LED chip bonded to the circuit board is tilted.

Based on this, the disclosure aims to provide a solution to the technical problems, details of which will be described in the following embodiments.

The embodiment provides a detection film. The detection film is configured to detect a tilt angle of a chip bonded to a circuit board. During detection, the chip bonded to the circuit board may be covered with the detection film. The detection film includes a film layer and colloidal crystal microspheres distributed in the film layer. All the colloidal crystal microspheres are arranged in the film layer in order. For convenience of understanding, a detection film 2 shown in FIG. 2 is described as an example below.

As shown in FIG. 2, the detection film 2 includes a film layer 21 and colloidal crystal microspheres 22 distributed in the film layer 21. It should be understood that a shape and a size of the detection film 2 in the embodiment may be flexibly set according to use requirements that include, but are not limited to, the number of chips to be detected, a distribution condition of chips, etc., which are not limited in the embodiment. The chips to be detected in the embodiment may include, but be not limited to, luminous chips. The luminous chips may include, but be not limited to, luminous microchips. The luminous microchips in the embodiment are um-level luminous chips, which, for example, may include, but be not limited to, at least one kind of Mini LED chips and Micro LED chips. Certainly, the luminous microchips may be further replaced with luminous chips having common or large sizes as required, which will not be repeated herein. In addition, the chips to be detected in the embodiment are not limited to the luminous chips, but may be further equivalently replaced with other chips, such as driver chips, resistor chips, capacitor chips and field-programmable gate array (FPGA) chips as required.

In the embodiment, the colloidal crystal microspheres 22 distributed in the film layer 21 are arranged in order, which are arranged in a three-dimensional space in a three-dimensional and orderly manner. A schematic diagram with the colloidal crystal microspheres 22 arranged in the film layer 21 in order is as shown in FIG. 3.

In the embodiment, during detection, the chip bonded to the circuit board may be covered with the detection film 2. It should be understood that the chip bonded to the circuit board may be directly covered with the detection film 2 and the detection film makes direct contact with the chip, or the detection film may be located above the chip bonded to the circuit board and makes no direct contact with the chip. Based on a Bragg reflection effect of the colloidal crystal microspheres, after bonding of each chip, when some chips are tilted, light reflected by colloidal crystal microspheres corresponding to chips having different tilt angles varies (a color or wavelength is different). Therefore, a tilt angle of each chip after bonding may be determined on the basis of light reflected by the colloidal crystal microspheres on the chip due to the Bragg reflection effect. In this way, whether the chip bonded to the circuit board is tilted is determined, that is, whether the chip bonded to the circuit board is tilted is detected. Poor light emitting effect and display effect caused by the fact that an unqualified chip after bonding is used in a subsequent process are avoided, so as to be more conducive to improvement in a yield of lighting products or display products and reduction of cost.

In an example in the embodiment, the colloidal crystal microspheres in the film layer may include, but be not limited to, nanosized colloidal crystal microspheres. For example, a particle size of any one of the colloidal crystal microspheres may be greater than or equal to 173 nanometers and less than or equal to 190 nanometers. For example, in some use scenes, a particle size of any one of the colloidal crystal microspheres may be, but not limited to, 173 nanometers, 175 nanometers, 180 nanometers, 189 nanometers or 190 nanometers. It should be understood that in some use examples, all the colloidal crystal microspheres 22 shown in FIG. 3 may have consistent particle sizes, or some colloidal crystal microspheres 22 may have different particle sizes. Certainly, in some use scenes in the embodiment, a particle size of any one of the colloidal crystal microspheres 22 may further be micronsized or less than nanosizes.

In the embodiment, a material of the colloidal crystal microspheres distributed in the film layer may further be flexibly selected under the condition of satisfying the Bragg reflection effect. For example, the colloidal crystal microspheres include, but are not limited to, at least one kind of silicon dioxide (Sio2) microspheres and polymer microspheres. The polymer microspheres may include, but be not limited to, at least one kind of polystyrene microspheres, polyacrylic acid microspheres, and nanosized microspheres copolymerized by various monomers. It should be understood that in some examples of the embodiment, the colloidal crystal microspheres distributed in the film layer may be made of one material. For example, the colloidal crystal microspheres may be one kind of Sio2 microspheres, polystyrene microspheres, polyacrylic acid microspheres, and nanosized microspheres copolymerized by various monomers. Certainly, in some use scenes, the colloidal crystal microspheres distributed in the film layer may further include colloidal crystal microspheres of various materials. For example, the colloidal crystal microspheres may be at least two kinds of Sio2 microspheres, polystyrene microspheres, polyacrylic acid microspheres, and nanosized microspheres copolymerized by various monomers.

In the embodiment, gaps between all the colloidal crystal microspheres are filled with at least part of film materials for forming the film layer. In some examples of the embodiment, the colloidal crystal microspheres may account for 74% of a total volume of the detection film, and the film materials may account for the rest 26%. Certainly, a volume ratio of the colloidal crystal microspheres to the film materials for forming the film layer may be flexibly set according to the use requirements. It should be understood that a material of the film materials for forming the film layer in the embodiment may be flexibly selected according to the use requirements, which may be, but not limited to, polydimethylsiloxane (PDMS), that is, a material of the film layer in the embodiment includes PDMS, which may be, certainly, equivalently replaced with other materials.

For convenience of understanding, a principle of detecting the tilt angle of the chip after bonding by means of the detection film is illustrated below in combination with a Bragg reflection principle.

A comprehensive refractive index n of the detection film may be computed according to the following formula (1).

$${n}^{2} = ( 1 - Φ ) {n}_{microsphere}^{2} + Φ {n}_{film material}^{2} \qquad ( 1 )$$

In formula (1), Φ is a ratio of the film materials to the total volume of the detection film, n_{microsphere} is a refractive index of the colloidal crystal microspheres, and n_{film matetial} is a refractive index of the film materials.

A Bragg formula refers to formula (2):

$$k * λ = 2 * \sqrt{\frac{2}{3}} * \sqrt{{n}^{2} - {sin}^{2} θ} * D \qquad ( 2 )$$

In formula (2), k is coefficient, D is a particle size of any one of the colloidal crystal microspheres, n is the comprehensive refractive index of the detection film, and θ is a light incident angle. Therefore, when materials of the colloidal crystal microspheres and the film materials are selected, the comprehensive refractive index n may be determined. A wavelength of a chip that is not tilted after bonding may be determined by obtaining a normal light incident angle θ in a preset light environment and then selecting a preset standard color (also called an initial color). For example, when blue is selected, a wavelength A of blue may be determined. Then, the parameters are substituted into formula (2), and a value of the particle size D of crystal microspheres may be obtained. Further, when the detection film is formed, the detection film may be formed by using the material and particle size of any one of the colloidal crystal microspheres determined and the film materials of a determined material. In this way, when the chip after bonding is in a same detection environment, a color of light reflected by colloidal crystal microspheres on a chip that is not tilted after bonding is the same as or different from the preset standard color within a preset standard range; and a color of light reflected by colloidal crystal microspheres on a tilted chip is different from the preset standard color, or is different from the preset standard color out of the preset standard range. Certainly, the color of the light may be equivalently replaced with the wavelength. Therefore, the detection film provided in the embodiment may be used to detect whether the chip after bonding is tilted, and a specific tilt angle range may be determined as required. Poor light emitting effect and display effect caused by the fact that an unqualified chip after bonding is used in a subsequent process are avoided, so as to be more conducive to improvement in a yield of lighting products or display products and reduction of cost. Moreover, the detection film in the embodiment is reusable, and a detection result may be further directly observed according to the color of the light, resulting in simple and convenient detection, low cost and desirable environmental protection.

### ANOTHER OPTIONAL EMBODIMENT

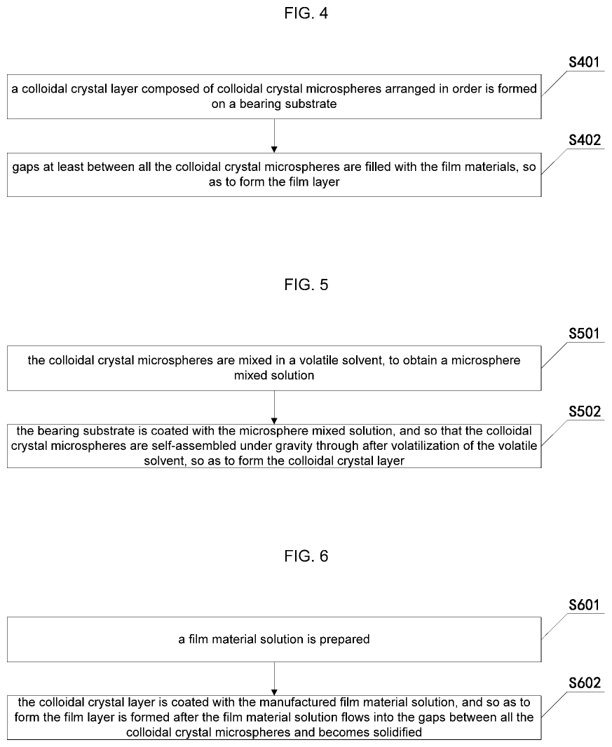

For convenience of understanding, the embodiment provides a manufacturing method for a detection film as an example, which is used to manufacture the detection film mentioned above. As shown in FIG. 4, the manufacturing method for a detection film provided in the embodiment includes:

S401: a colloidal crystal layer composed of colloidal crystal microspheres arranged in order is formed on a bearing substrate.

It should be understood that a material of the bearing substrate in the embodiment may be flexibly selected, which may be, but not limited to, a silicon substrate and a quartz substrate, or may be replaced with other materials.

In the embodiment, a mode in which the colloidal crystal layer composed of the colloidal crystal microspheres arranged in order is formed on the bearing substrate is as shown in FIG. 5, which may include, but be not limited to:

S501: the colloidal crystal microspheres are mixed in a volatile solvent, to obtain a microsphere mixed solution.

Matched colloidal crystal microspheres are selected and dispersed in the volatile solvent, so as to obtain the microsphere mixed solution. Moreover, a selected volatile solvent has no influence on film materials for forming a film layer. For example, when the film materials are PDMS, the selected volatile solvent may be, but not limited to, an oil phase solvent, such as isopropanol having a low boiling point and other inert solvents (which are an oil phase solvents and not water-phase) that are volatile and have no influence on PDMS. The colloidal crystal microspheres (such as SiO2 microspheres) are dispersed in isopropanol or other inert solvents that are volatile and have no influence on PDMS, so as to obtain the microsphere mixed solution.

S502: the bearing substrate is coated with the microsphere mixed solution, so that the colloidal crystal microspheres self-assemble under gravity after volatilization of the volatile solvent, so as to form the colloidal crystal layer.

The bearing substrate is coated with the microsphere mixed solution, so that the colloidal crystal microspheres self-assemble under gravity by using a volatile characteristic of the volatile solvent, so as to form a three-dimensional ordered body or face cubic structure similar to that shown in FIG. 3.

In some examples of the embodiment, the bearing substrate is evenly coated by means of technologies including, but not limited to, spin coating, ink-jet printing or spray coating.

S402: gaps at least between all the colloidal crystal microspheres are filled with the film materials, so as to form the film layer. For example, an example of forming the film layer is as shown in FIG. 6, which includes, but is not limited to:

S601: a film material solution is prepared.

For example, prepolymer A of polydimethylsiloxane and cross-linking agent B of the polydimethylsiloxane are mixed, and then dilution is conducted with a diluent, so as to obtain the film material solution. A viscosity of the formed film material solution may be, but not limited to, 20 mPa's·50 mPa·s. The diluent in the embodiment may be flexibly selected, which, for example, may be, but not limited to, acetone, methanol or an n-hexane solvent as the diluent.

S602: the colloidal crystal layer is coated with the manufactured film material solution, so as to form the film layer after the film material solution flows into the gaps between all the colloidal crystal microspheres and becomes solidified. Coating in the operation may be conducted in modes including, but not limited to, drop coating in addition to various coating modes in the examples.

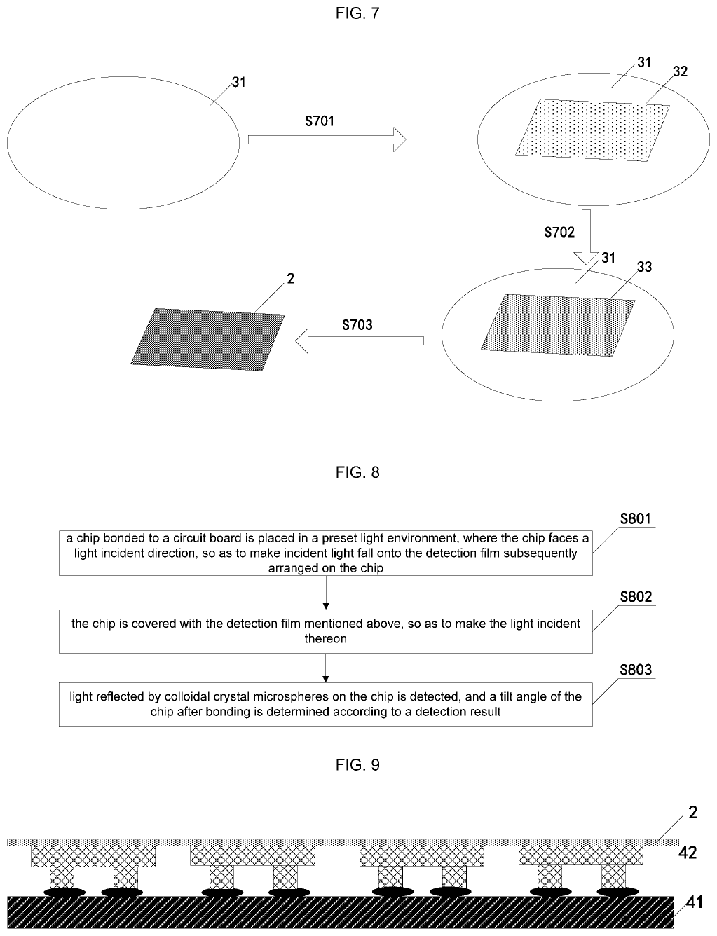

For convenience of understanding, a manufacturing process of a detection film shown in FIG. 7 is described as an example below, which includes, but is not limited to:

S701: the bearing substrate 31 is spin-coated with the manufactured microsphere mixed solution, so as to form the microsphere mixed solution 32.

According to the volatile characteristic of the volatile solvent, after the volatile solvent volatilizes, the colloidal crystal microspheres are self-assembled under gravity, so as to form the colloidal crystal layer.

S702: the colloidal crystal layer is drop-coated with the manufactured film material solution, so as to form a film material solution layer 33.

In the operation, the detection film 2 is formed after the film material solution flows into the gaps between all the colloidal crystal microspheres and becomes solidified.

S703: the detection film 2 is separated from the bearing substrate 31. A thickness of the detection film 2 may be flexibly set according to the use requirements, which is not limited herein.

It may be seen that the manufacturing method for a detection film provided in the embodiment is simple and efficient, has low cost, and may achieve mass production.

Yet another optional embodiment:

For convenience of understanding, the embodiment describes a method for detecting a chip bonding condition by means of the detection film mentioned above in the embodiment as an example below. As shown in FIG. 8, a detection method for chip bonding provided in the embodiment includes, but is not limited to:

S801: a chip bonded to a circuit board is placed in a preset light environment, where the chip faces a light incident direction, so as to make incident light fall onto the detection film subsequently arranged on the chip.

In the embodiment, the preset light environment in S801 may be a preset natural light environment or a preset light source irradiation environment, as long as light incident on the detection film satisfies a detection condition. The circuit board in the embodiment may include, but be not limited to, a display back panel and various circuit boards for lighting.

S802: the chip is covered with the detection film mentioned above, so as to make the light incident thereon.

S803: light reflected by colloidal crystal microspheres on the chip is detected, and a tilt angle of the chip after bonding is determined according to a detection result.

With reference to formula (2), in an example of the embodiment, the operation that light reflected by colloidal crystal microspheres on the chip is detected, and a tilt angle of the chip after bonding is determined according to a detection result may include, but be not limited to:

An actual color of the light reflected by the colloidal crystal microspheres on the chip is observed, and the tilt angle of the chip after bonding is determined according to a difference between the actual color and a preset standard color. Observation in the embodiment may be conducted visually and directly by human eyes, and a detection mode is simple and effective.

For example, in an example, when the colloidal crystal microspheres are Sio2 microspheres and film materials are PDMS, n of the manufactured detection film is a constant value, and a particle size of the corresponding selected Sio2 microspheres is 173 nanometers-190 nanometers. In this case, the light reflected by the colloidal crystal microspheres has a wavelength of 420 nanometers-460 nanometers, and may show blue. Therefore, in some examples, the Sio2 microspheres having the particle size of 173 nanometers-190 nanometers may be selected to form the detection film. When the preset standard color is blue, whether the actual color of the light reflected by the colloidal crystal microspheres on the chip is blue is observed. If not, the chip after bonding may be determined to be tilted.

Based on the principle, after a test, a particle size of Sio2 microspheres is selected to be 189 nanometers for a specific single blue wavelength, which shows a blue wavelength of 457 nanometers. Therefore, in some examples, the Sio2 microspheres having the particle size of 189 nanometers may be selected to form a colloidal crystal layer, and the preset standard color is blue. It should be understood that, based on the principle, the preset standard color may be adjusted accordingly by flexibly adjusting at least one of the material and particle size of any one of the colloidal crystal microspheres and the film materials, which is not limited to a corresponding relation between the material and particle size of Sio2 and the blue wavelength in the example.

With reference to formula (2), in another example of the embodiment, the operation that light reflected by colloidal crystal microspheres on the chip is detected, and a tilt angle of the chip after bonding is determined according to a detection result includes:

An actual wavelength λ1 of the light reflected by the colloidal crystal microspheres on the chip is obtained.

According to obtained λ1, an actual light incident angle θ1 of the chip is computed according to the following formula (3):

$$k * λ 1 = 2 * \sqrt{\frac{2}{3}} * \sqrt{{n}^{2} - {sin}^{2} θ 1} * D \qquad ( 3 )$$

In formula (3), k is a coefficient, D is a particle size of any one of the colloidal crystal microspheres, and n is a comprehensive refractive index of the detection film.

The tilt angle of the chip after bonding is determined according to a difference between the actual light incident angle θ1 and a preset standard light incident angle θ₀.

The standard light incident angle θ₀ in the embodiment is a light incident angle obtained in the detection environment when the chip after bonding is not tilted. Therefore, whether the corresponding chip is tilted may be determined according to the difference between the actual light incident angle θ1 and a preset standard light incident angle θ₀. In addition, a tilt angle value or tilt angle range of the corresponding chip may further be determined according to a specific difference therebetween.

It may be seen that through the detection method provided in the embodiment, when the chip after bonding is tilted, according to a Bragg formula, an actual light incident tilt angle changes due to tilting, that is, e changes in formula (2), and λ changes when D and n are determined, such that a color of the light reflected by the colloidal crystal microspheres changes, thereby showing a color difference. Moreover, in some examples, when different chips have different tilt angles, a color of light reflected by colloidal crystal microspheres thereon varies. Through statistical analysis, a specific tilt condition may be further determined according to a corresponding color of light, such as colors corresponding to different tilt angles. Therefore, during detection, a tilt condition of each chip may be intuitively determined according to a color of light reflected by colloidal crystal microspheres on the chip, resulting in simple detection, high efficiency, low cost and high accuracy.

For convenience of understanding, a specific use scene is described as an example below.

With reference to a display panel shown in FIG. 9, the display panel includes one or more luminous chips 42 bonded to a display back panel 41. It is assumed that no luminous chips 42 shown in FIG. 9 are tilted after bonding. When the display panel is placed in the preset light environment, a color of light reflected by colloidal crystal microspheres on the luminous chips 42 may be used as a standard color, and a light incident angle may be used as the standard light incident angle θ₀. In an example shown in FIG. 9, the detection film 2 may have a certain rigidity and be directly arranged on the luminous chips 42. Certainly, in some examples, a packaging layer may further be arranged on the display back panel 41. The packaging layer may fill a gap between adjacent luminous chips 42, and may be flush with the luminous chips 42 or higher than the luminous chips 42 and cover all the luminous chips 42. The detection film 2 may be arranged on the packaging layer. The packaging layer in the embodiment may be flexibly set, and, for example, may include a packaging rubber layer, or a luminous conversion layer, a color resistance layer, a light isolation layer, etc. that are arranged on the luminous chips 42.

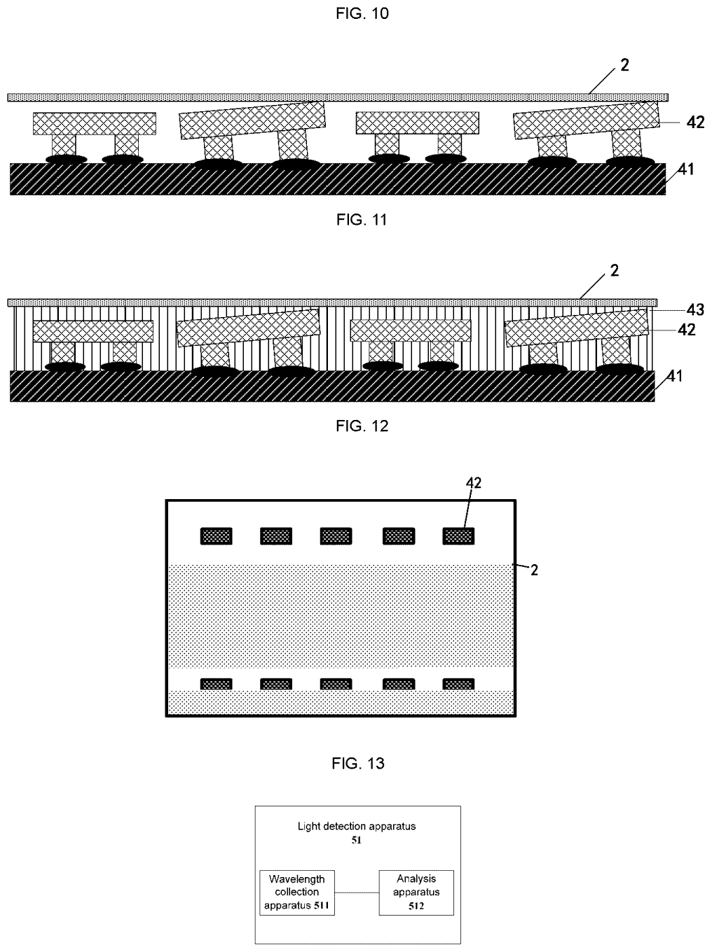

With reference to the display panel shown in FIG. 10, the luminous chips 42 on the display panel in FIG. 10 are bonded to the display back panel 41, and then placed in the preset light environment, and the detection film 2 is arranged on each luminous chip 42. An actual color of light reflected by colloidal crystal microspheres on a tilted luminous chip is different from the standard color. In addition, the actual light incident angle θ1 may be computed according to an actual wavelength of the light reflected by the colloidal crystal microspheres on the tilted luminous chip and formula (3), and whether the corresponding chip is tilted may be determined according to the difference between the actual light incident angle θ1 and the preset standard light incident angle θ₀.

As shown in FIGS. 11 and 12, the display back panel 41 is further provided with the packaging layer 43, and the detection film 2 is arranged on the packaging layer 43, thereby making the packaging layer 43 relatively flat, so as to be more conducive to detection. The actual color of the light reflected by the colloidal crystal microspheres on the tilted luminous chip is different from the standard color. In addition, the actual light incident angle θ1 may be computed according to the actual wavelength of the light reflected by the colloidal crystal microspheres on the tilted luminous chip and formula (3), and whether the corresponding chip is tilted may be determined according to the difference between the actual light incident angle θ1 and the preset standard light incident angle θ₀.

The embodiment further provides a detection device for chip bonding. The detection device includes:

a light detection apparatus configured to in a case where a chip bonded to a circuit board is placed in a preset light environment, the chip faces a light incident direction, and the detection film according to claim 1 covers the chip, detect light reflected by colloidal crystal microspheres on the chip, and determine, according to a detection result, a tilt angle of the chip after bonding. A mode of determining the tilt angle of the chip after bonding according to the detection result may refer to, but not limited to, the examples. For example, in an example, as shown in FIG. 13, the light detection apparatus 51 includes, but is not limited to:

a wavelength collection apparatus 511 configured to collect an actual wavelength λ1 of the light reflected by the colloidal crystal microspheres on the chip, wherein the wavelength collection apparatus 511 may be, but not limited to, a spectrometer; and an analysis apparatus 512 configured to compute an actual light incident angle θ1 of the chip according to λ1 obtained by the wavelength collection apparatus 511 and formula (3), and determine, according to a difference between the actual light incident angle θ1 and a preset standard light incident angle θ₀, the tilt angle of the chip after bonding.

In some other examples of the embodiment, the detection device may further include a conveying device for conveying a transfer device to be detected to the preset light environment, or a light source device for generating a corresponding light source, etc.

Another optional embodiment:

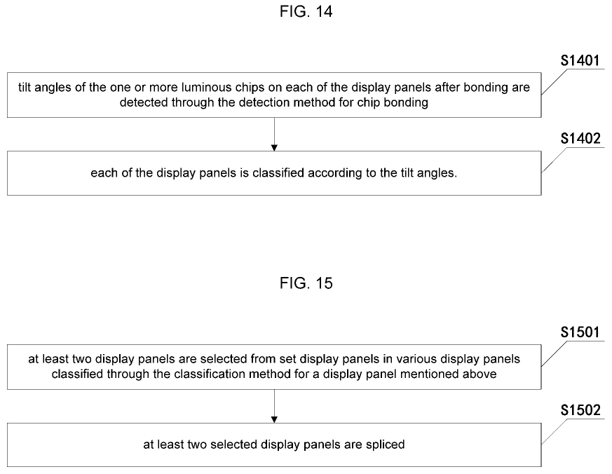

The embodiment provides a classification method for display panels. Each of the display panels includes a display back panel and one or more luminous chips bonded to the display back panel. As shown in FIG. 14, the classification method includes:

S1401: tilt angles of the one or more luminous chips on each of the display panels after bonding are detected through the detection method for chip bonding mentioned above.

S1402: each of the display panels is classified according to the tilt angles.

For example, in some examples, the tilt angles may be classified according to a preset operation size. If falling within a corresponding operation size, a maximum tilt angle, an average tilt angle or a minimum tilt angle of the tilted luminous chips on the display panel may be classified into a class corresponding to the operation size, which may be specifically set flexibly according to use requirements. In some examples, when the tilt angle exceeds a certain threshold, corresponding luminous chips are determined to be unqualified and need to be repaired.

The embodiment further provides a manufacturing method for a display screen. As shown in FIG. 15, the manufacturing method includes:

S1501: at least two display panels are selected from set display panels in various display panels classified through the classification method for a display panel mentioned above.

S1502: at least two selected display panels are spliced. In the embodiment, a splicing mode is not limited.

That is, in the embodiment, based on a detection technology for chip bonding provided in the embodiment, display panels may be classified in advance. According to different customer specification requirements, display panels having similar or complementary tilt angles of chips are selected for splicing. In this way, the problem of squint spots in an existing large line display screen is solved, so as to improve overall quality of the display screen.

The embodiment further provides a display screen that includes a frame and a display panel. The display panel is fixed to the frame. The display screen may be used for, but not limited to, various intelligent mobile terminals, vehicle-mounted terminals, personal computers (PCs), displays, electronic advertisement boards, etc.

It should be understood that application of the disclosure is not limited to the examples and that modifications or variations may be made for those of ordinary skill in the art in light of the description, all of which are intended to fall within the scope of protection of the appended claims of the disclosure.

1. A detection film, being configured to cover a chip bonded to a circuit board, and comprising a film layer and colloidal crystal microspheres distributed in the film layer, wherein the colloidal crystal microspheres are arranged in the film layer in order.

2. The detection film according to claim 1, wherein the colloidal crystal microspheres are nanosized colloidal crystal microspheres.

3. The detection film according to claim 2, wherein a particle size of any one of the colloidal crystal microspheres is greater than or equal to 173 nanometers and less than or equal to 190 nanometers.

4. The detection film according to claim 1, wherein the colloidal crystal microspheres comprise at least one kind of silicon dioxide microspheres and polymer microspheres.

5. The detection film according to claim 1, wherein a material of the film layer comprises polydimethylsiloxane.

6. The detection film according to claim 1, wherein a total volume of the colloidal crystal microspheres account for 74% of a total volume of the detection film.

7. A manufacturing method for a detection film, wherein the detection film is configured to cover a chip bonded to a circuit board; and the manufacturing method for the detection film comprises:
forming, on a bearing substrate, a colloidal crystal layer composed of colloidal crystal microspheres arranged in order; and
filling gaps at least between all the colloidal crystal microspheres with film materials, so as to form a film layer.

8. The manufacturing method for a detection film according to claim 7, wherein forming, on the bearing substrate, the colloidal crystal layer composed of colloidal crystal microspheres arranged in order comprises:
mixing the colloidal crystal microspheres in a volatile solvent, to obtain a microsphere mixed solution; and
coating the bearing substrate with the microsphere mixed solution, so that the colloidal crystal microspheres self-assemble under gravity after volatilization of the volatile solvent, so as to form the colloidal crystal layer.

9. The manufacturing method for a detection film according to claim 8, wherein the volatile solvent comprises an oil phase solvent.

10. The manufacturing method for a detection film according to claim 7, wherein filling gaps at least between all the colloidal crystal microspheres with film materials, so as to form the film layer comprises:
preparing a film material solution; and
coating the colloidal crystal layer with the film material solution, so as to form the film layer after the film material solution flows into the gaps between all the colloidal crystal microspheres and becomes solidified.

11. The manufacturing method for a detection film according to claim 10, wherein preparing the film material solution comprises:
mixing prepolymer A of polydimethylsiloxane and cross-linking agent B of the polydimethylsiloxane, and then conducting dilution with a diluent, so as to obtain the film material solution.

12. A detection method for chip bonding, comprising:
placing a chip bonded to a circuit board in a preset light environment;
covering the chip with the detection film according to claim 1; and
detecting light reflected by colloidal crystal microspheres on the chip, and determining, according to a detection result, a tilt angle of the chip after bonding.

13. The detection method for chip bonding according to claim 12, wherein the preset light environment is a preset natural light environment, or a preset light source irradiation environment.

14. The detection method for chip bonding according to claim 12, wherein detecting the light reflected by colloidal crystal microspheres on the chip, and determining, according to the detection result, the tilt angle of the chip after bonding comprise:
observing an actual color of the light reflected by the colloidal crystal microspheres on the chip, and determining, according to a difference between the actual color and a preset standard color, the tilt angle of the chip after bonding.

15. The detection method for chip bonding according to claim 12, wherein detecting the light reflected by colloidal crystal microspheres on the chip, and determining, according to the detection result, the tilt angle of the chip after bonding comprise:
obtaining an actual wavelength λ1 of the light reflected by the colloidal crystal microspheres on the chip;
computing an actual light incident angle θ1 of the chip according to λ1 and the following formula:
$$k * λ 1 = 2 * \sqrt{\frac{2}{3}} * \sqrt{{n}^{2} - {sin}^{2} θ 1} * D ,$$
wherein k is a coefficient, D is a particle size of any one of the colloidal crystal microspheres, and n is a comprehensive refractive index of the detection film; and
determining, according to a difference between the actual light incident angle θ1 and a preset standard light incident angle θ₀, the tilt angle of the chip after bonding.

16. The detection method for chip bonding according to claim 12, wherein a packaging layer covering the chip is arranged on the circuit board, and covering the chip with the detection film according to claim 1 comprises:
covering the packaging layer with the detection film.

17. The detection method for chip bonding according to claim 12, wherein the chip comprises at least one of a mini light-emitting diode (LED) chip and a Micro LED chip.

18. A detection device for chip bonding, comprising:
a light detection apparatus configured to, in a case where a chip bonded to a circuit board is placed in a preset light environment, the chip faces a light incident direction, and the detection film according to claim 1 covers the chip, detect light reflected by colloidal crystal microspheres on the chip, and determine, according to a detection result, a tilt angle of the chip after bonding.

19. The detection device for chip bonding according to claim 18, wherein the light detection apparatus comprises:
a wavelength collection apparatus configured to collect an actual wavelength λ1 of the light reflected by the colloidal crystal microspheres on the chip; and
an analysis apparatus configured to compute an actual light incident angle θ1 of the chip according to λ1 and the following formula, and determine, according to a difference between the actual light incident angle θ1 and a preset standard light incident angle θ₀, the tilt angle of the chip after bonding,
wherein the formula is
$$k * λ 1 = 2 * \sqrt{\frac{2}{3}} * \sqrt{{n}^{2} - {sin}^{2} θ 1} * D ,$$
k is a coefficient, D is a particle size of any one of the colloidal crystal microspheres, and n is a comprehensive refractive index of the detection film.

20. A classification method for display panels, wherein each of the display panels comprises a display back panel and one or more luminous chips bonded to the display back panel, and the classification method comprises:
detecting, through the detection method for chip bonding according to claim 12, tilt angles of the one or more luminous chips on each of the display panels after bonding; and
classifying each of the display panels according to the tilt angles.
